(19) United States
(12) Patent Application Publication
(10) Pub. No.: US 2025/0133646 A1
(43) Pub. Date: Apr. 24, 2025

(54) HYDROGEN PLASMA REDUCTION OF METAL OXIDE FILMS TO METAL

(71) Applicant: Surfx Technologies LLC, Redondo Beach, CA (US)

(72) Inventors: Thomas Scott Williams, Long Beach, CA (US); Robert F. Hicks, Los Angeles, CA (US); Hsiao-Wen Liu, Taichung City (TW)

(73) Assignee: Surfx Technologies LLC, Redondo Beach, CA (US)

(21) Appl. No.: 18/924,853

(22) Filed: Oct. 23, 2024

Related U.S. Application Data
(60) Provisional application No. 63/545,316, filed on Oct. 23, 2023.

(51) Int. Cl. H05H 1/30; B23K 10/00

(52) U.S. Cl. CPC H05H 1/30; B23K 10/00; H05H 2245/40

(57) ABSTRACT

Metal oxide films are reduced to metal with an atmospheric pressure argon and hydrogen plasma at temperatures between 25 and 250° C. A 40-nm-thick copper oxide layer on a copper-coated silicon wafer, 300 mm in diameter, can be fully removed by the argon and hydrogen plasma in under two minutes at 150° C. The fast rate of metal oxide reduction to metal demonstrates that this process is well suited for front- and back-end semiconductor manufacturing, such as for example, flux-free flip chip bonding of microbumps.

### CROSS-REFERENCE TO RELATED APPLICATIONS

This application claims the benefit under 35 U.S.C. § 119(e) of the following U.S. provisional patent application, which is incorporated by reference herein:

U.S. Provisional Patent Application No. 63/545,316, filed Oct. 23, 2023, and entitled “HYDROGEN PLASMA REDUCTION OF METAL OXIDE FILMS TO METAL,” by Williams et al. (Attorney Docket SRFXP013.P1).

### BACKGROUND OF THE INVENTION

### 1. Field of the Invention

The invention is related to a plasma apparatus and methods of using the plasma apparatus for removing metal oxide films from metals. Particularly, the invention is related to reducing metal oxide films to metal using an atmospheric pressure argon and hydrogen plasma, wherein the metals are selected from the group comprising nickel, palladium, platinum, copper, silver, gold, gallium, indium, tin, lead, bismuth, and alloys thereof.

### 2. Description of Related Art

A plasma consists of an ionized gas, containing free electrons, positive ions, and negative ions. Plasmas are “quasi-neutral” meaning that the sum of the charges on the number of free electrons, positive ions and negative ions sums to zero. Plasmas used in materials processing are generally weakly ionized, meaning that a very small fraction of the species in the gas are charged. The free electrons in these gas discharges are accelerated to an extremely high velocity, exhibiting electron temperatures in the range of 1.0 to 3.0 electron volts (eV). These energetic electrons smash into molecules, such as oxygen (O₂) or hydrogen (H₂), and dissociate them into atoms, such as O or H. The atoms in turn react with other species in the gas or on the substrate and drive desired materials processes, such as surface cleaning and activation for adhesion, metal oxide removal for metal-metal bonding, etching of thin films, and deposition of thin films. For example, a copper oxide (CuO) film on a copper surface may be removed with H atoms by the reaction CuO+2H=Cu+H₂O. The physics and chemistry of weakly ionized plasmas are described in several textbooks. See for example, Lieberman and Lichtenberg, “Principles of Plasma Discharges and Materials Processing,” (John Wiley & Sons, Inc., New York, 2005); F. F. Chen and J. P. Chang, “Lecture Notes on Principles of Plasma Processing,” (KIuwer Academic/Plenum Publishers, New York, 2003); and Raizer, Y. P., “Gas Discharge Physics,” (Springer-Verlag, Berlin, 1991).

Over the past twenty-five years, atmospheric pressure plasmas have been developed as an alternative to vacuum plasmas. An atmospheric pressure plasma can produce a much higher concentration of reactive species than a vacuum plasma, and thereby process substrates at a faster throughput. This significantly reduces the cost to manufacture valuable products, such as semiconductor devices. The physics, chemistry and applications of atmospheric pressure plasmas are described in many publications (see for example: Winter, et al., “Atmospheric pressure plasma jets: an overview of devices and new directions,” Plasma Sources Science and Technology, vol. 24.6, p. 064001 (2015); Tendero, et al., “Atmospheric pressure plasmas: A review,” Spectrochimica Acta Part B: Atomic Spectro., vol 61.1, p. 2 (2006); and Schutze, et. al., “The atmospheric-pressure plasma jet: A review and comparison to other plasma sources,” IEEE Trans. Plasma Sci. 26, 1685-1694 (1998)). These gas discharges are governed by how the ionization process is controlled. At atmospheric pressure, the gas density is so high that the ionization reaction can run away and generate a high temperature arc, which is not useful for materials processing.

In U.S. Pat. Nos. 9,406,485, 10,032,609, 10,800,092 and 11,518,082, Cheng et al., describe a plasma apparatus and method that operates with argon or helium at atmospheric pressure and at low temperatures, and produces a high concentration of reactive species in the effluent stream. The ions and electrons uniformly fill the gas volume between the electrodes, with a collisional sheath forming at the boundaries to repel the electrons and maintain the plasma. The atmospheric pressure argon (or helium) plasma is driven by a radio frequency (RF) power source at 27.12 MHz. Most likely an RF power source at 13.56 MHz could also be used for this application. Depending on the RF power level, the neutral gas temperature ranges from 323 to 573 K. Molecular gases are fed with the helium or argon at concentrations from 0.5 to 5.0 volume %.

Moravej, et al., in “Physics of High-Pressure Helium and Argon Radio-Frequency Plasmas,” J. Appl. Phys., vol. 96, p. 7011 (2004), has shown that weakly ionized, uniform glow plasmas can be generated at atmospheric pressure. In these plasmas, the average electron density is between 10¹¹ to 10¹² cm⁻³, whereas the neutral gas density is 2.0×10¹⁹ cm⁻³. The average electron temperature is in the range of 1.0 to 2.0 eV. These authors found that the argon plasma is much more difficult to stabilize than the helium plasma for several reasons. The cross section of argon is large, comparable to that of nitrogen and oxygen molecules, yielding a higher rate of ionization. Secondly, the mass of argon is twenty times larger than helium, which reduces the electron mobility in the gas. In order to maintain a reasonable current through the argon discharge, the electron density is raised to a value greater than 10¹² cm⁻³, where it is possible for the plasma to transition from alpha- to gamma-mode ionization (see Yang, et al., “Comparison of an Atmospheric Pressure, Radio-Frequency Discharge Operating in the Alpha and Gamma Modes,” Plasma Sources Sci. Technol., vol. 14, p. 314 (2005); and Shi and Kong, “Mechanisms of the Alpha and Gamma Modes in Radio-Frequency Atmospheric Glow Discharges,” J. Appl. Phys., vol. 97, p. 023306 (2005)). When the alpha- to gamma-mode transition occurs, the protective sheath at the electrode walls breaks down and ionizes. This process causes the plasma to collapse into a small spot where it is no longer uniform, and no longer useful for materials processing.

To maintain a uniform, weakly ionized argon plasma at atmospheric pressure, it is necessary to limit the RF power to a value safely below the alpha- to gamma-mode transition. Cheng, et al., in U.S. Pat. No. 9,406,485 disclose that a 25-mm linear beam plasma was operated at 150 to 180 W with 15.0 liters per minute (LPM) argon and 0.5 LPM oxygen. The oxygen plasma was used to clean and activate the surfaces of silicon, alumina ceramic, carbon-fiber reinforced epoxy composite, polyimide, polyurethane, polyethylene, aluminum, and titanium. Activation rates were found to be faster with the atmospheric pressure argon plasma than with the atmospheric pressure helium plasma.

Cheng, et al., in U.S. Pat. Nos. 9,406,485, 10,032,609, 10,800,092 and 11,518,082, disclose that copper oxide may be removed from copper by treatment with an atmospheric pressure argon and hydrogen plasma. A 25-mm linear beam plasma source was operated at 160 W with 15.0 LPM argon and 1.0 LPM forming gas (95% nitrogen and 5% hydrogen). In another experiment, the 25-mm linear beam plasma was operated at 150 W with 10.0 LPM argon and 0.2 LPM pure hydrogen. In both cases, the plasma source was scanned over a copper substrate at 2 to 3 millimeters distance. The thick copper oxide on the surface of the metal, causing it to have a purple color, was removed revealing the characteristic copper color of the reduced metal. The rate of etching the copper oxide away was not described.

Joyce, et al. in “Atmospheric pressure plasma reduction of copper oxide to copper metal,” J. Vac. Sci. Technol. A., vol. 39, p. 023001 (2021), has disclosed the removal of copper oxide from copper with an atmospheric pressure argon and hydrogen plasma. These authors measured the rate of etching copper oxide (CuO) with the plasma beam at different substrate temperatures. The rate of etching depended on whether the sample was a copper lead frame, or a film of copper metal deposited on a silicon wafer. The effect of temperature on the CuO removal rate recorded for the copper film on the wafer is shown in Table 1. The rate increases approximately ten times as the substrate temperature is raised from 25 to 250° C. At 150° C., the oxide removal rate is found to be 0.2 nanometers per second (nm/s).

TABLE 1
Copper oxide removal from copper films on silicon
wafers, from the work of Joyce, et al., J. Vac.
Sci. Technol. A. vol. 39, p. 023001 (2021).

| Temperature | CuO Removal | Scan Speed | Process |
|---|---|---|---|
| (° C.) | Rate (nm/s) | (mm/s) | Time (min) |
| 25 | 0.05 | 0.19 | 61.6 |
| 100 | 0.10 | 0.39 | 30.8 |
| 150 | 0.20 | 0.78 | 15.4 |
| 200 | 0.25 | 0.97 | 12.3 |
| 250 | 0.53 | 2.07 | 5.8 |
| 300 | 1.23 | 4.79 | 2.5 |

In the study by Joyce, et al., the copper oxide was removed using an Atomflo™ 600 atmospheric plasma system with a 100-mm linear beam plasma operated at 500 W radio frequency power (27.12 MHz), 33.0 LPM argon, 7.0 LPM forming gas (95% nitrogen and 5% hydrogen), and a standoff distance from the sample of 2 mm. In Table 1, the scan speed required to remove a 40 nm thick copper oxide layer from a copper film on a silicon wafer is shown. This value is calculated using the methods in Joyce et al.'s publication. A 40-nm-thick layer of CuO on Cu will give the metal a brown tarnished color.

Also listed in Table 1 is the time required to complete the oxide removal process on a 300 mm wafer. Since the plasma beam is 100 mm wide, three scans across the diameter of the wafer are needed, i.e., 3×300=900 mm in total. The process time in minutes equals 900/S/60, where S is the scan speed in mm/s. It is obvious to someone skilled in the art that this process is too slow for commercial application, requiring 12 to 15 minutes to complete at substrate temperatures in the range of 150 to 200° C. Thus, there is a need for a copper oxide removal process that is much faster, achieving a throughput for 300 mm wafers that is a few minutes or less at substrate temperatures below 200° C.

Besides copper, there are other metals used in semiconductor manufacturing that would benefit from removal of the metal oxide using an atmospheric pressure argon and hydrogen plasma. For example, this process could be used to deoxidize two-dimensional arrays of metal microbumps on flip chips. The metal microbumps consist of tin-silver alloy caps on copper pillars. Microbump arrays with a pitch (i.e., spacing) between the pillars of less than 50 microns (μm) requires removal of the oxide from the tin-silver solder caps in a way that does not leave behind organic residue. Use of an organic flux is not an option. The atmospheric pressure argon and hydrogen plasma would remove the oxidation without generating organic residue, but to be of commercial use, the removal rate must be substantially higher than indicated in Table 1. In view of the foregoing, there is a need for a plasma device and method that is suitable for removing metal oxidation from metals at throughputs suitable for semiconductor manufacturing. These and other needs are met by embodiments of the present invention as described hereafter.

### SUMMARY OF THE INVENTION

One embodiment of the invention comprises an atmospheric pressure plasma apparatus that is fed with at least argon and hydrogen gas to remove metal oxidation from metals selected from the group comprising nickel, palladium, platinum, copper, silver, gold, gallium, indium, tin, lead, bismuth, and alloys thereof. The plasma is generated in a housing through which the gas flows and contacts two electrodes. The electrodes are driven by radio frequency power sufficient to break down the gas and convert it to an ionized gas discharge. A high density of hydrogen radicals is generated within this device by collisions between hydrogen molecules and energetic free electrons. The hydrogen radicals flow out of the device and onto a substrate that is placed downstream. The substrate comprising a surface with metal features upon it is contacted with the H atoms, and the metal oxide on the surface of the metal features is rapidly removed by the reaction, MOₓ₍ₛ₎+2xH_{(g)}=M₍ₛ₎+xH₂O_{(g)}, where the subscripts s and g refer to solid and gas, respectively. In the case of copper, the reaction is CuO₍ₛ₎+2H_{(g)}=Cu₍ₛ₎+H₂O_{(g)}. In one embodiment of the invention, the substrate comprises one or more semiconductor devices, in the form of a die, wafer, board, panel, or other structure used in manufacturing and packaging integrated circuits.

In another embodiment of the invention, the atmospheric pressure plasma source, that is fed with at least argon and hydrogen gas, generates a high density of hydrogen radicals across a linear beam that extends in length from 10 to 300 mm. The hydrogen radicals flowing out of the plasma device are uniformly distributed across said beam. In one embodiment of the invention, the self-contained plasma device is scanned over a substrate whose width is the same or less than the width of the plasma beam, and the metal oxidation on the surface of the metal features on the substrate is rapidly removed at a uniform rate over the entire substrate by contact with the hydrogen radicals from the plasma beam. In another embodiment of the invention, the self-contained plasma device is scanned over a substrate whose width is greater than the width of the plasma beam, and the metal oxidation on the surface of the metal features is removed at a uniform rate over the entire substrate by incrementally scanning and stepping the plasma beam over said substrate.

In another embodiment of the invention, the atmospheric pressure plasma source is combined with a chamber that houses the substrate, and said chamber is filled with inert gas, selected from the group argon and nitrogen. Inside the chamber, the substrate is contracted with the high density of hydrogen radicals in a gas flow that is substantially free of oxygen. The plasma apparatus and chamber are designed to allow the linear plasma beam to be scanned over the substrate such that the substrate is uniformly contacted with the high density of hydrogen radicals, and the metal oxidation is rapidly removed from the metal features distributed over the entire substrate. The inert gas in the chamber may be supplied directly from the self-contained plasma device, or it may be supplied separately to the chamber in addition to the gas flow provided by the plasma device. In this embodiment of the invention, a gas flow substantially free of oxygen means that the oxygen concentration is below 1,000 parts per million (ppm).

In another embodiment of the invention, the atmospheric pressure plasma source, driven with RF power and fed with argon and hydrogen gas, generates a high concentration of hydrogen radicals in an argon flow that is substantially free of particles. The hydrogen radicals flowing out of the self-contained plasma device are uniformly distributed across a linear beam from 10 to 300 mm in width. Said beam of reactive gas contacts a substrate and removes metal oxidation from metal features on the substrate without substantially depositing particles on the surface, at particle sizes equal to or greater than 0.1 micron in diameter. In one embodiment of the invention, the atmospheric pressure plasma apparatus, driven with RF power and fed with argon and hydrogen gas, is scanned over a substrate, and removes metal oxidation from metal features on the surface without substantially depositing particles, wherein said substrate comprises one or more semiconductor devices, in the form of a die, wafer, board, panel, or other structure used in manufacturing and packaging integrated circuits.

Another embodiment of the invention is a method of rapidly removing metal oxidation from metal surfaces by contact with the hydrogen radicals flowing out of an atmospheric pressure plasma source. Said plasma source is driven with radio frequency power and is fed with a gas flow of at least argon and hydrogen. In this embodiment of the invention, the plasma is generated in a linear beam that extends from between 10 and 300 mm wide, and hydrogen radicals generated in the plasma beam flow out of the device and uniformly contact the substrate. The plasma device is scanned over the substrate to remove metal oxidation from metal features on the surface at a throughput on the order of several minutes or less. In this method of removing metal oxidation from metal features on the surface, the process is completed without substantially depositing particles on the surface with particle sizes equal to or greater than 0.1 micron in diameter.

Another embodiment of the invention comprises an apparatus and method for depositing thin films. The self-contained plasma device is combined with a gas injector for volatile precursor molecules and a chamber that houses the substrate and is fed with an inert gas, selected from the group argon and nitrogen. Inside the chamber, the substrate is contracted with the high density of hydrogen radicals flowing out of the plasma device as well as with the volatile precursor molecules flowing out of the injector. The hydrogen radicals and precursor molecules react with each other, causing a coating to be deposited on the substrate. The chamber is designed such that the plasma device and injector may be scanned over the substrate to deposit a uniform coating, wherein the gas environment is kept substantially free of oxygen throughout the deposition process, i.e., the oxygen concentration is maintained below 1,000 ppm. The volatile precursor molecules are selected such that their reaction with the hydrogen radicals generates a coating with the desired composition and structure on the substrate.

Another exemplary embodiment comprise an apparatus for removing metal oxide layers from metals including a chamber filled with inert gas such that an oxygen concentration in the chamber is kept below 1,000 parts per million, an atmospheric pressure plasma source disposed in the chamber that is fed with argon and hydrogen, generates hydrogen radicals, and operates at a linear power density greater than 10.0 W/mm, a temperature-controlled plate disposed within the chamber, wherein said temperature-controlled plate supports a substrate including metal features with a metal oxide layer upon the surface of the metal features, and a means for moving the substrate and the atmospheric pressure plasma source relative to each other, such that the hydrogen radicals flowing out of the plasma source contact and convert the metal oxide layer to metal and water vapor. The power supply can operate at a radio frequency of 13.56 or 27.12 MHz. The inert gas can be selected from the group argon and nitrogen. The hydrogen can be added to the argon gas flow through the plasma is at a concentration between 0.1 to 5.0 volume %. The substrate can be heated to a temperature between 20 and 250° C. The substrate can be selected from the group of semiconductor materials comprising, integrated circuits, chips, dies, wafers, panels, chip packages, and printed circuit boards. The metal can be selected from the group comprising, nickel, palladium, platinum, copper, silver, gold, gallium, indium, tin, lead, bismuth and alloys thereof. The metal features can be a two-dimensional array of microbumps with copper pillars and tin alloy solder caps having a diameter less than 100 microns, and the metal oxide layer on the tin alloy solder caps is removed.

In further embodiments, the plasma source can comprise a linear opening that produces a beam of reactive gas between 1 and 300 mm wide. The linear opening can be at least as wide as the substrate containing the metal features with the metal oxide layer to be removed.

An exemplary method of removing metal oxide layers from metals comprises filling a chamber with inert gas such that an oxygen concentration in the chamber is kept below 1,000 parts per million, disposing an atmospheric pressure plasma source within the chamber and operating it with argon and hydrogen gas flows and a radio frequency power source with a power density greater than 10.0 W/mm to generate hydrogen radicals, disposing a temperature-controlled plate within the chamber, wherein said temperature-controlled plate supports a substrate including metal features with a metal oxide layer upon the surface of the metal features, and moving the substrate and the plasma source relative to each other, such that the hydrogen radicals flowing out of the plasma source contact and convert the metal oxide layer to metal and water vapor. This method embodiment of the invention can be further modified consistent with any of the apparatus or method embodiments described herein.

Another exemplary embodiment comprises a device for forming metal interconnects comprising a chamber filled with inert gas such that an oxygen concentration in the chamber is kept below 1,000 parts per million, an atmospheric pressure plasma source disposed within the chamber, wherein said atmospheric pressure plasma source is fed with argon and hydrogen and operates at a linear power density greater than 10.0 W/mm, a bond head disposed in the chamber, wherein said bond head holds a flip chip with microbumps on it at a temperature between 20 and 250° C., a temperature-controlled plate disposed inside the chamber and heated to between 20 and 250° C., wherein said temperature-controlled plate supports a substrate including microbumps or metal pads that are of substantially similar dimensions of the microbumps on the flip chip, and a means for scanning the bond head with the flip chip over the plasma source and down onto the substrate, such that the metal oxidation on the microbumps is removed by the plasma and the flip chip is bonded to the substrate forming said metal interconnects. This apparatus embodiment of the invention can be further modified consistent with any of the apparatus or method embodiments described herein.

Another exemplary embodiment comprises a method of forming metal interconnects comprising filling a chamber with inert gas such that an oxygen concentration in the chamber is kept below 1,000 parts per million, disposing an atmospheric pressure plasma source within the chamber, wherein said source is fed with argon and hydrogen and operates at a linear power density greater than 10.0 W/mm, mounting a bond head in the chamber, wherein said bond head holds a flip chip with microbumps on it at a temperature between 20 and 250° C., disposing a temperature-controlled plate inside the chamber and heating it to between 20 and 250° C., wherein said temperature-controlled plate supports a substrate including microbumps or metal pads that are of substantially similar dimensions of the microbumps on the flip chip, and scanning the bond head with the flip chip over the plasma source and down onto the substrate, such that the metal oxidation on the microbumps is removed by the plasma and the flip chip is bonded to the substrate forming said metal interconnects. This method embodiment of the invention can be further modified consistent with any of the apparatus or method embodiments described herein.

Yet another exemplary embodiment comprises an apparatus for plasma-enhanced chemical vapor deposition of thin films including a chamber filled with inert gas such that an oxygen concentration in the chamber is kept below 1,000 parts per million, an atmospheric pressure plasma source disposed within the chamber, wherein said atmospheric pressure plasma source is fed with argon and hydrogen and operates at a linear power density greater than 10.0 W/mm to generate hydrogen radicals, a gas injector disposed in the chamber, wherein said gas injector is fed with volatile precursor molecules that include one or more elements to be deposited in a thin film, a temperature-controlled plate placed in the chamber and heated to between 20 and 500° C., wherein said plate holds a substrate, and a means for moving the substrate and the plasma source and gas injector relative to each other, such that the hydrogen radicals flowing out of the plasma source combine with the precursor molecules flowing out of the injector and react together and deposit the thin film on the substrate. This apparatus embodiment of the invention can be further modified consistent with any of the apparatus or method embodiments described herein.

Yet another exemplary embodiment comprises a method of depositing a thin film on a substrate including filling a chamber with inert gas such that an oxygen concentration in the chamber is kept below 1,000 parts per million, disposing an atmospheric pressure plasma source within the chamber, wherein said atmospheric pressure plasma source is fed with argon and hydrogen and operates at a linear power density greater than 10.0 W/mm to generate hydrogen radicals, disposing a gas injector in the chamber, wherein said gas injector is fed with volatile precursor molecules that include one or more elements to be deposited in a thin film, disposing a temperature-controlled plate in the chamber and heating the temperature-controlled plate to between 20 and 500° C., wherein said temperature-controlled plate supports a substrate, and moving the substrate and plasma source and gas injector relative to each other, such that the hydrogen radicals flowing out of the plasma source combine with the precursor molecules flowing out of the injector and react together and deposit the thin film on the substrate. This method embodiment of the invention can be further modified consistent with any of the apparatus or method embodiments described herein.

These and other embodiments of the invention will become apparent to those skilled in the art from the following drawings and detailed description of the preferred embodiments.

### BRIEF DESCRIPTION OF THE DRAWINGS

Referring now to the drawings in which like reference numbers represent corresponding parts throughout:

FIG. 1 is schematic diagram of an exemplary argon and hydrogen plasma apparatus for removing metal oxidation from metal features on a substrate.

FIG. 2 shows an image of two pieces of a copper-coated silicon wafer after oxidation at 150° C. for 5 minutes and 30 seconds. The copper oxide film has a brown appearance indicative of a copper oxide layer 40 nanometers (nm) thick.

FIG. 3 shows samples of a copper-coated silicon wafer after scanning them at 5, 10 and 15 mm/s with the 25-mm linear beam plasma source fed with argon and hydrogen and operated at 180 W RF power. The wafer was kept at 150° C. during plasma treatment.

FIG. 4 shows samples of a copper-coated silicon wafer after scanning them at 20, 25, 30 and 40 mm/s with the 25-mm linear beam plasma source with argon and hydrogen and operated at 550 W RF power. The wafer was kept at 150° C. during plasma treatment.

FIG. 5 shows samples of a copper-coated silicon wafer after scanning them at 10, 15 and 20 mm/s with the 50-mm linear beam plasma source fed with argon and hydrogen and operated at 270 W RF power. The wafer was kept at 150° C. during plasma treatment.

FIG. 6 shows samples of a copper-coated silicon wafer after scanning them at 15, 20 and 25 mm/s with a 50-mm linear beam plasma source fed with argon and hydrogen and operated at 580 W RF power. The wafer was kept at 150° C. during plasma treatment.

FIG. 7 shows samples of a copper-coated silicon wafer after scanning them at 25 mm/s with a 50-mm linear beam plasma source fed with argon and hydrogen and operated at 580 W RF power. The wafer was temperature was held at 130,150 and 190° C. during each plasma treatment.

FIG. 8 is a schematic drawing of an exemplary plasma source for an embodiment of the invention shown with an inert gas purged environment with the activated feed gas from the plasma to remove metal oxide from a substrate.

FIG. 9 presents a side view and isometric view of an exemplary linear beam plasma source.

FIG. 10 presents an outlet view of an exemplary linear beam plasma source.

FIG. 11 is schematic diagram of an exemplary apparatus for metal oxide removal and bonding of flip chips with microbumps at atmospheric pressure using the argon and hydrogen plasma in an inert gas environment.

FIG. 12 is schematic diagram of an exemplary apparatus for plasma-enhanced chemical vapor deposition of thin films at atmospheric pressure using the argon and hydrogen plasma in an inert gas environment.

### DETAILED DESCRIPTION INCLUDING THE PREFERRED EMBODIMENTS

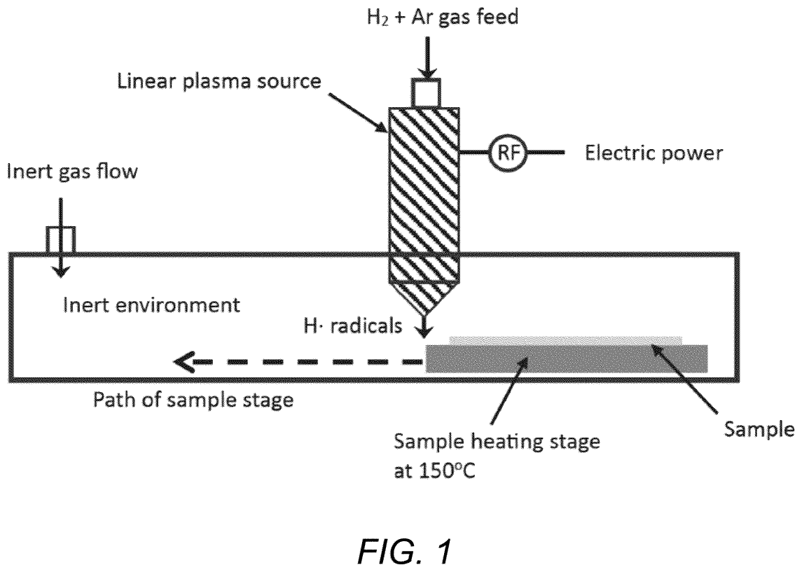

Shown in FIG. 1 is a schematic of the atmospheric pressure plasma apparatus. The linear plasma source is mounted onto a chamber. The chamber is fed with argon or nitrogen to create an inert gas environment where the concentration of oxygen is less than 1,000 ppm, preferably less than 100 ppm. A temperature-controlled sample stage is placed within the chamber which can be heated to between 20 to 250° C. The sample containing metal features to be treated with the atmospheric pressure plasma is placed on top of the heated stage. The sample can be selected from a wide variety of different materials that would be obvious to those skilled in the art. For example, the sample can be a silicon wafer with integrated circuits embedded in it, or it can be a semiconductor die, a lead frame strip, a printed circuit board, or any other substrate used in the manufacture of microelectronic devices. A robot is placed beneath the heated stage (not shown in the schematic) and used to scan the sample underneath the plasma beam at a fixed speed ranging from 0 and 1,000 mm/s.

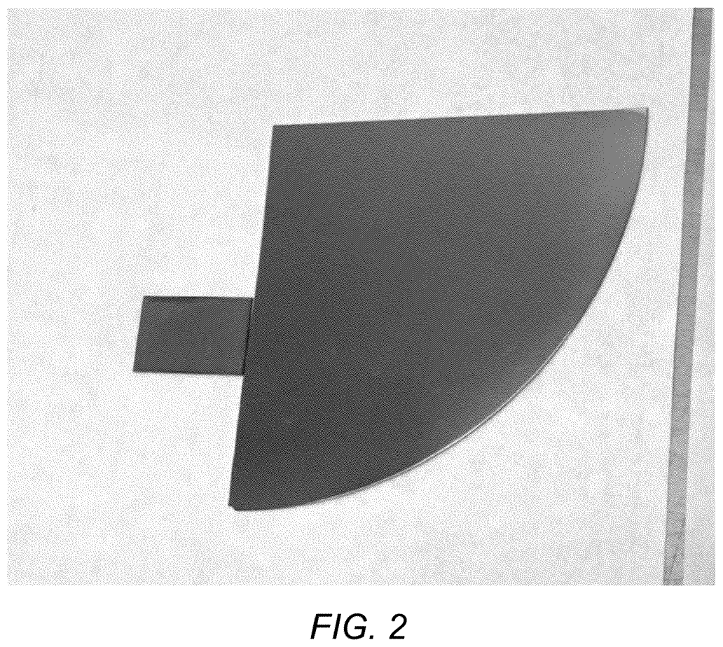

An example of samples to be treated with the atmospheric pressure argon and hydrogen plasma is presented in FIG. 2. The picture shows two pieces cut from a copper-coated silicon wafer 200 mm in diameter. The copper coating is one hundred nanometers (nm) thick. On the right, is one quarter of the Cu-coated silicon wafer. On the left, is a smaller piece, 25×25 mm². These samples were heated at 150° C. in air for 5 minutes and 30 seconds. During heating, the copper turned orangish brown due to the formation of a copper oxide (CuO) layer approximately 40 nm thick. In the examples that follow, small pieces will be put in the apparatus described in FIG. 1 and treated with the plasma to remove the 40-nm-thick copper oxide layer.

The process used to remove the copper oxide is as follows: The sample is placed on the temperature-controlled stage inside the chamber, and the chamber purged out with a constant flow of argon to reduce the residual oxygen concentration in the gas below 1,000 ppm. The sample is heated from 20° C. to 150° C. Then, the atmospheric pressure argon and hydrogen plasma is turned on and scanned over the sample at a fixed speed. After treatment, the sample is cooled back down to room temperature in the inert gas flow. Finally, the sample is removed from the chamber and examined to see if the brown copper oxide layer has been removed.

### Example 1

Method of Removing Copper Oxide from Copper with 25-mm Linear Beam Plasma

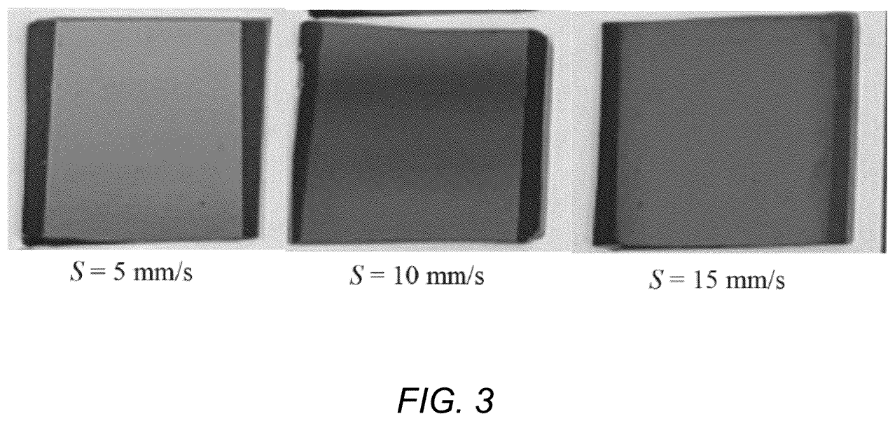

Shown in FIG. 3 are samples of Cu-coated silicon wafers that have been treated with the 25-mm-wide argon and hydrogen plasma at 5, 10 and 15 mm/s scan speed. The temperature-controlled stage is at 150° C., and a standard plasma recipe is used of 180 W RF power, 9.9 LPM total gas flow, and 1.1 volume % hydrogen. At a scan speed of 5 mm/s, nearly all the copper oxide has been removed. However, at scan speeds of 10 and 15 mm/s, the treated area exhibits an orange color with a brown tinge, indicating that not all the copper oxide has been removed. These data demonstrate that to remove 40 nm of CuO from Cu at 150° C. and 180 W RF power, a scan speed of 5 mm/s or less is required.

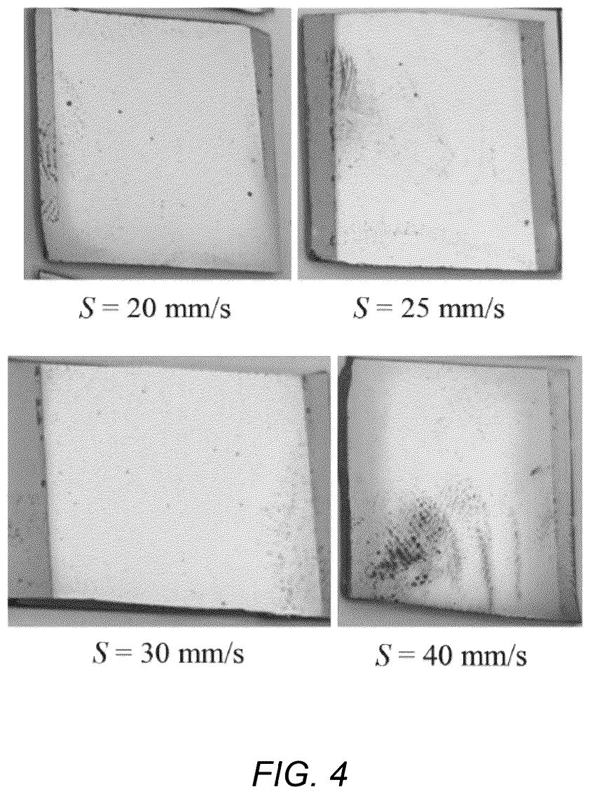

Presented in FIG. 4 are samples of Cu-coated silicon wafers that have been treated with the 25-mm-wide argon and hydrogen plasma at 20, 25, 30 and 40 mm/s scan speed, and with the RF power at 550 W. The total flow rate fed to the plasma is 19.0 LPM and the hydrogen concentration is 1.8 volume %. The sample is held at 150° C. in this case. Except for the sample scanned at 40 mm/s, the treated area exhibits a bright copper color, indicating that all the oxide has been removed. Thus, the high-power recipe for the 25-mm linear beam plasma (550 W, 19.0 LPM gas flow, and 1.8% hydrogen) is at least 6 times faster than the standard recipe for the 25-mm linear beam plasma (180 W, 9.8 LPM gas flow, and 1.1% hydrogen). In the example where a 40-nm-thick copper oxide layer must be removed from a copper film on a 300 mm wafer, the 25-mm linear beam plasma source would need to be scanned 12 times across the diameter of the wafer in order to cover the entire surface. At a scan speed of 30 mm/s, this process would be completed in 2 minutes. This is much faster than the process time of 15.4 minutes reported by Joyce and coworkers (as seen in Table 1 above). In short, the present invention provides for a significant improvement in the plasma process for oxide removal from metal features on semiconductor substrates.

### Example 2

Method of Removing Copper Oxide from Copper with 50-mm Linear Beam Plasma

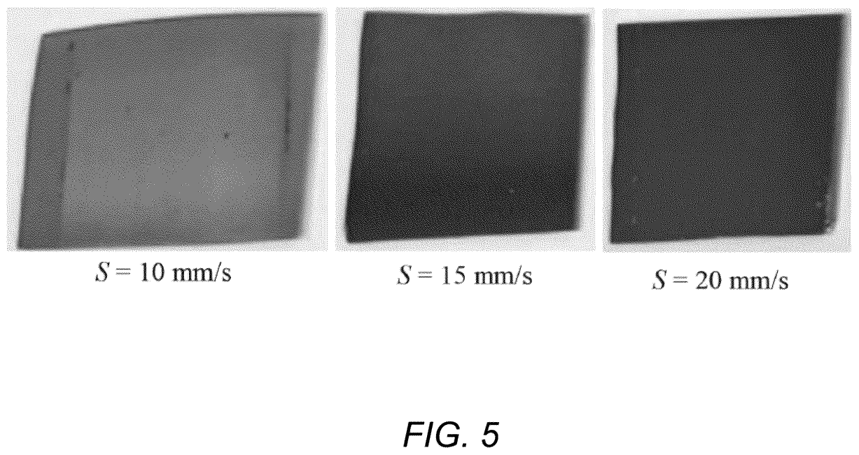

Shown in FIG. 5 are samples of Cu-coated silicon wafers that have been treated with the 50-mm-wide argon and hydrogen plasma at 10, 15 and 20 mm/s scan speed. A standard plasma recipe is used of 270 W RF power, 19.6 LPM gas flow, and 1.1 volume % hydrogen. The temperature-controlled stage is kept at 150° C. The samples used in these experiments were approximately 25×25 mm². The edges of the samples were held down onto the hot plate with a thin strip of Kapton tape. Referring to FIG. 5, no significant etching of the copper oxide is observed at scan speeds of 15 and 20 mm/s, while at 10 mm/s, some fraction of the CuO has been removed. In a separate experiment, a scan speed of 5 mm/s was found to remove all the oxidation from the copper film.

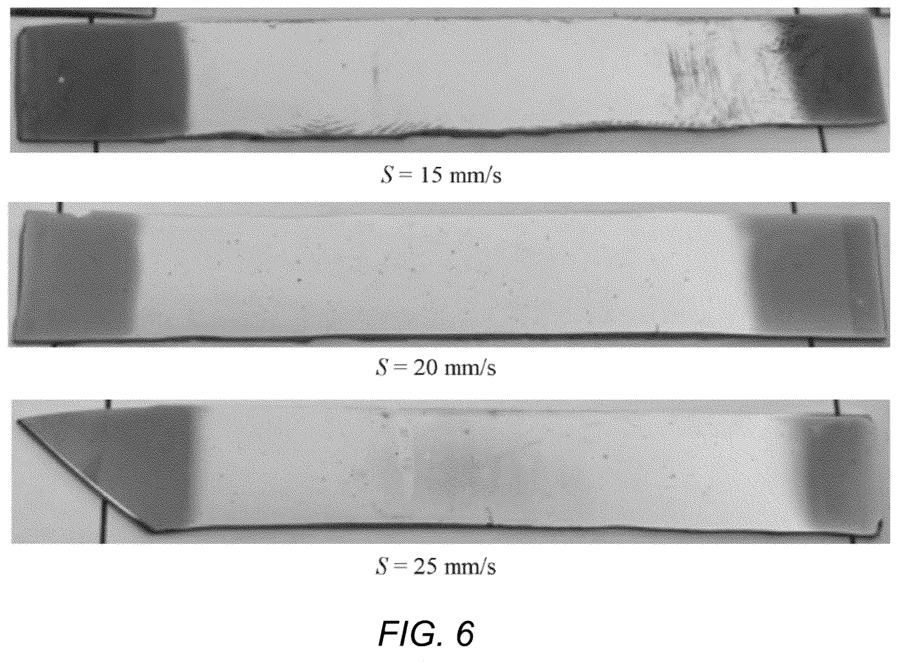

FIG. 6 presents samples of Cu-coated silicon wafers that have been treated with the 50-mm-wide argon and hydrogen plasma at an RF power of 580 W, and with the sample held at 150° C. Plasma scan speeds of 15, 20 and 25 mm/s have been examined. The gas flow rate into the plasma is 55.0 LPM and the hydrogen concentration is 1.4 volume %. All three samples exhibit a bright copper color, demonstrating that the oxide has been completely removed at every scan speed. The 580-W recipe for the 50-mm linear beam plasma source is at least 5 times faster than the standard 270-W recipe (i.e., FIG. 5). In the example where a 40-nm-thick copper oxide layer is removed from a copper film on a 300 mm wafer, the 50-mm linear beam plasma would have to be scanned 6 times across the diameter of the wafer in order to cover the entire surface. At a scan speed of 25 mm/s, this process would be completed in 1.2 minutes. This is nearly thirteen times faster than the process time reported by Joyce and coworkers at the same sample temperature of 150° C. (refer to Table 1). In summary, the present invention is a dramatic improvement over the prior art.

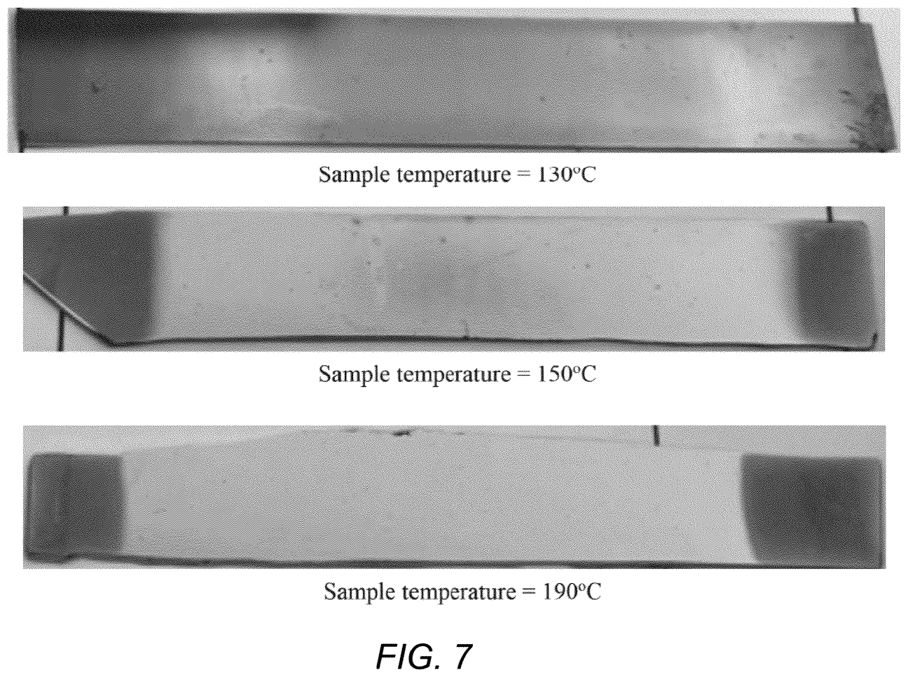

FIG. 7 shows the results for copper oxide removal with the 50-mm-wide argon and hydrogen plasma at 580 W RF power and substrate temperatures of 130, 150 and 190° C. In every case, the scan speed is 25 mm/s, the total flow rate is 55.0 LPM, and the hydrogen concentration is 1.4 volume %. It is seen that the rate of copper oxide removal increases with substrate temperature. A scan speed of 25 mm/s is not sufficient to remove the 40-nm CuO layer at 130° C., is just sufficient to remove it at 150° C., and more than sufficient to remove it at 190° C. Note that the edge of the plasma beam scan over the surface is sharper in the image of the sample treated at 190° C. compared to that treated at 150° C. A similar dependence on substrate temperature has been reported previously by Joyce, et al. (J. Vac. Sci. Technol. A. vol. 39, p. 023001 (2021)). They observed a thermal activation energy of 3.7 kcal/mole for the etching of copper oxide with an argon and hydrogen plasma at atmospheric pressure.

TABLE 2
Comparison of the CuO removal rates with
the 25- and 50-mm linear beam plasmas.

| | | | Power | Scan | Process |
|---|---|---|---|---|---|
| Plasma Head | RF Power | H₂ Conc. | Density | Speed | Time |
| Width (mm) | (W) | (%) | (W/mm) | (mm/s) | (min) |
| 25 | 180 | 1.1 | 7.2 | 5.0 | 12.0 |
| 25 | 550 | 1.8 | 22.0 | 30.0 | 2.0 |
| 50 | 270 | 1.1 | 5.4 | 5.0 | 6.0 |
| 50 | 580 | 1.4 | 11.6 | 25.0 | 1.2 |

A comparison of the results achieved for the 25- and 50-mm-wide plasma sources is presented in Table 2. The third column in the table shows the linear power density (W/mm), where the RF power input is divided by the width of the plasma beam. It is evident that at power densities above 10 W/mm, the copper oxide layer is removed at a much faster rate with the atmospheric pressure argon and hydrogen plasma. For the 25-mm-wide plasma source, the CuO etch rate is six times faster at a power density of 22.0 W/mm compared to that at 7.2 W/mm. A similar large increase in CuO etch rate is seen with the 50-mm-wide plasma source. The last column in Table 2 lists the time required to completely remove 40 nm of copper oxide from a copper film on top of a 300 mm silicon wafer. At equivalent scan speeds, the 50-mm-wide plasma beam will complete the process twice as fast as the 25-mm-wide plasma beam. These results suggest that an atmospheric plasma source with a 100 mm wide beam operating at 22.0 W/mm, or 2.2 kW, will remove the 40 nm CuO layer from a 300 mm wafer in just 30 seconds. Such a result would be of great advantage to the semiconductor manufacturing industry and highlights the significance of this invention.

### Example 3

Comparison of Atmospheric Pressure Plasmas Operating with Argon and Oxygen Versus Argon and Hydrogen

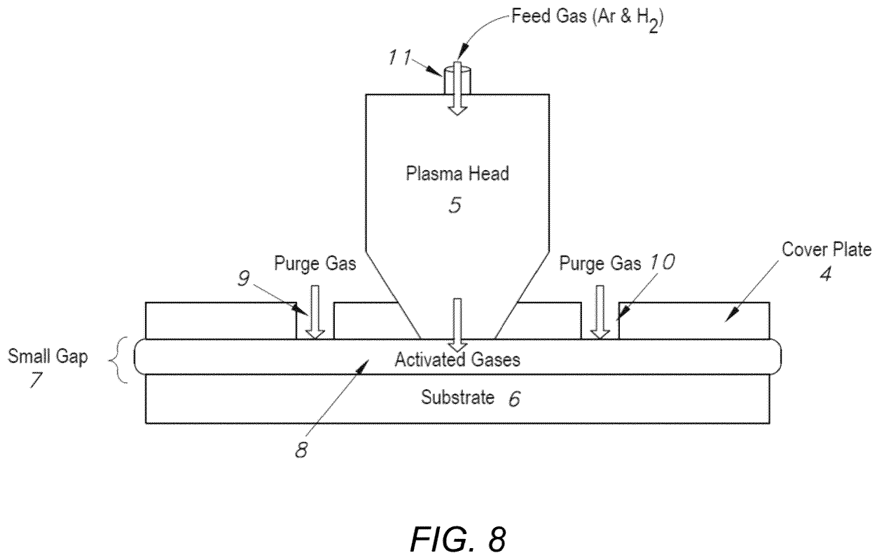

In FIG. 8, a schematic is presented of an exemplary plasma source (or head) 5 for embodiments of the invention which combines an inert gas purged environment with the activated feed gas (either argon and hydrogen or argon and oxygen) from the plasma to remove metal oxide. The plasma source comprises an optional cover plate 4 that can be attached directly to the plasma head 5. Feed gas enters the plasma head 5 at the inlet 11, and is converted into a weakly ionized plasma, producing free electrons, ions and activated gases. The activated gases 8 flow out of the plasma head 5 through a linear outlet slit 12 and contact the metal substrate 6. The cover plate 4 and plasma head 5 are flush with each other and are mounted above the substrate 6, maintaining a small gap 7 between the plasma head 5 and metal substrate 6. Air is quickly displaced from the gas volume in the small gap 7 by the activated gas flow. Suitable gap spacings are 0.1 to 5.0 mm, and preferably between 0.1 and 2.0 mm. Additional purge gas may be introduced through purge holes 9 and 10 in the cover plate 4. The purge gas is selected from the group of inert gases, argon and nitrogen. The purge gas assists the activated gas in displacing air from the gas volume in the gap 7, such that an inert gas environment is maintained during removal of the metal oxide from the metallic contacts by the activated hydrogen. An inert gas environment is defined as one where the oxygen concentration is low enough to not cause reoxidation of the metal substrate 6 after exposure to the activated hydrogen generated by the plasma process. Examples of an inert gas environment is where the oxygen concentration is below 1,000 ppm, and preferably below 100 ppm. Exemplary purge holes 9 and 10 can comprise elongated slits or one or more holes through which the purge gas flows around the activated gases 8.

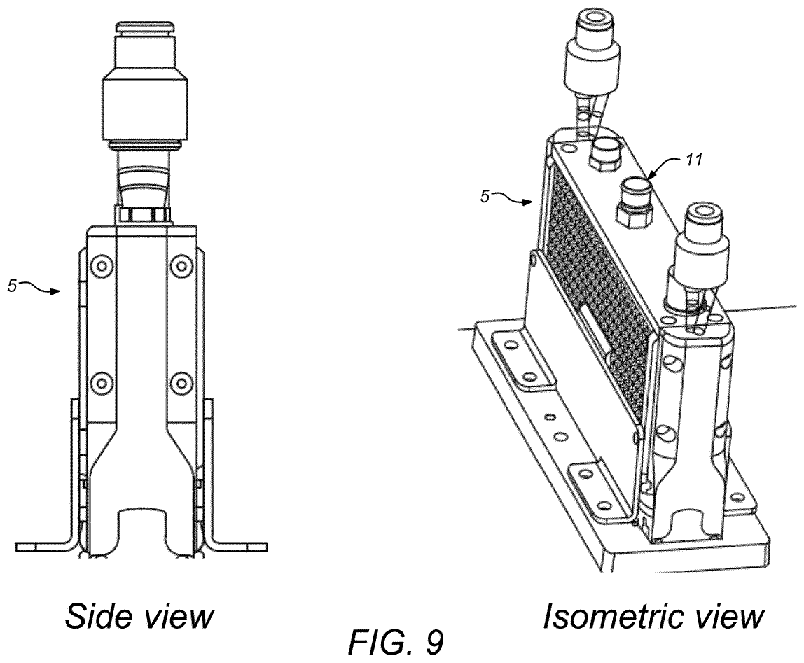

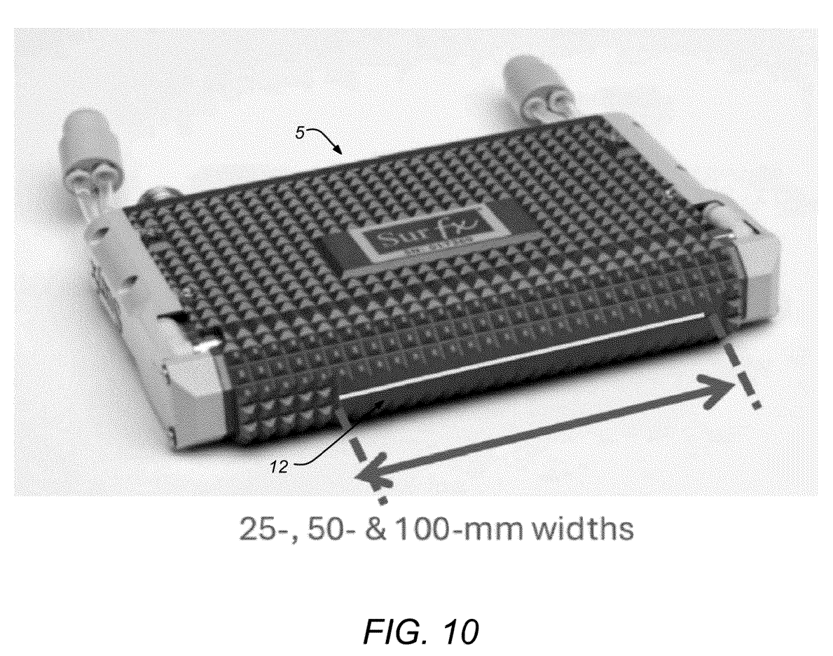

A slight positive pressure is established within the gap 7 such that there is sufficient gas flow to expel all the air out the perimeter of the cover plate 4. This allows the plasma reduction process to occur in an inert gas environment with a concentration of oxygen below 500 ppm. The low oxygen environment facilitates the removal of the metal oxide and prevents re-oxidation of the metal particularly when the substrate 6 is heated. Shown in FIG. 9 are side and isometric views of an exemplary 25-mm linear beam plasma source, consistent with the schematic of FIG. 8. Shown in FIG. 10 is an outlet of an exemplary linear beam plasma source, consistent with the schematic of FIG. 8 and views of FIG. 9. FIGS. 8-10 illustrate an exemplary plasma source which can be implemented with any of the of the embodiments described herein using feed gas mixtures of argon and oxygen or argon and hydrogen with variable combination as well as an adjustable linear beam width (25 mm, 50 mm, or 100 mm widths) and adjustable RF power level for plasma generation. Note although 25 mm width beam can be used in the following examples, 50 mm, and 100 mm widths are also possible with this exemplary plasma source.

In one process, the exemplary plasma source can be adjusted to deliver a 25-mm wide linear beam and operating with argon and oxygen feed gases. The process recipe is defined: 150 W RF power, 8.0 LPM argon flow, and 0.03 LPM oxygen flow. Upon looking into the outlet slit one sees a bright glow that is distributed uniformly across the width of the beam. No bright spots are evident. From a side view, a thin sheet of glowing gas can be observed extending about 10 mm out of the exit slit. The glow is due to metastable oxygen molecules that emit visible light upon collisional deexcitation (Jeong, et al., “Reaction Chemistry in the Afterglow of an Oxygen-Helium, Atmospheric-Pressure Plasma,” J. Phys. Chem. A, vol. 104, p. 8027 (2000)). If the device is operated at much higher input powers, such as above 200 W, the gas discharge becomes unstable and exhibits a non-uniform glow with bright spots and streamers observed downstream of the slit. At high enough power, an arc can form in a small region between the powered electrode and ground, which can damage the device. These observations and other facts known to those skilled in the art show that the uniform glow discharge exists over a limited range of power levels. For the linear beam plasma source operating with argon and oxygen, the high-power limit is found to be 180, 300 and 580 W for slit widths of 25, 50 and 100 mm, respectively. These power limits correspond to a linear plasma density between 5.8 and 7.2 W/mm.

In another process, the exemplary plasma source can be again adjusted to deliver a 25-mm wide linear beam operating with argon and hydrogen. This process recipe is defined: 180 W RF power, 7.7 LPM argon flow, and 2.1 LPM of 5.0% hydrogen in argon. The outlet view reveals a uniform glow distributed evenly across the slit. The visible emission is due to transitions between excited states of argon atoms and excited states of hydrogen atoms (Golloch, et al., “Atomic Emission Spectrometry,” De Gruyter, Berlin (2020)). In the side view, no glow is visible, because there are no excited states of argon or hydrogen atoms that live long enough to exist downstream of the plasma region between the powered and grounded electrodes. The linear power density applied in this case is 7.2 W/mm.

In yet another process, the 25-mm linear beam plasma source can be operated with argon and hydrogen at high power. This process recipe is defined: 450 W RF power, 7.7 LPM argon flow, and 2.1 LPM of 5.0% hydrogen in argon. The outlet view reveals a uniform glow distributed evenly across the slit. The glow observed for this recipe is significantly brighter than the glow observed at 180 W (i.e., FIG. 9). The side view again does not show any visible glow, and there are no streamers emitted from the slit either. Unlike the atmospheric pressure argon and oxygen plasma, this plasma does not become unstable at high RF powers. The linear power density in this case is 18.0 W/mm. The high RF power density recorded here, and in the examples listed in Table 2 above are unexpected, and they demonstrate the unusually high stability of the atmospheric pressure argon and hydrogen plasma.

### Example 4

Method of Removing Oxidation from Microbumps on Flip Chips

John H. Lau in “Semiconductor Advanced Packaging,” Springer Nature, Singapore (2021) presents many examples that utilize microbumps on flip chips to make the interconnections between integrated circuits in two- and three-dimensional (2D and 3D) semiconductor packages. A microbump consists of a copper pillar with a solder cap on it comprised of tin or tin-metal alloys, such as Sn—Ag. The microbumps are distributed in a 2D army across the bottom of the chip. The dimensions of the bumps can range from 8 to 50 microns (μm), and the distance between the bump centers, i.e., the pitch, can range from 10 to 150 μm. During packaging, the chip (or die) is flipped over, picked up and bonded to a package or another die by thermocompression bonding (TCB). A flip chip with microbumps having a pitch of 10 μm can have one million interconnections per cm², and is highly desired in advanced computing applications, such as artificial intelligence.

The tin solder caps on the copper pillars contain a layer of metal oxide that must be removed before or during thermocompression bonding. Traditionally, organic flux has been used to eliminate the oxide by forming tin formate that sublimes off the surface when the chip is heated. However, this process leaves behind organic residues which are difficult if not impossible to get rid of at pitch sizes below 50 μm. An attractive alternative to flux is the removal of the metal oxide from the solder caps by treatment with the atmospheric pressure argon and hydrogen plasma. In this case, the metal oxide removal process occurs immediately prior to bonding.

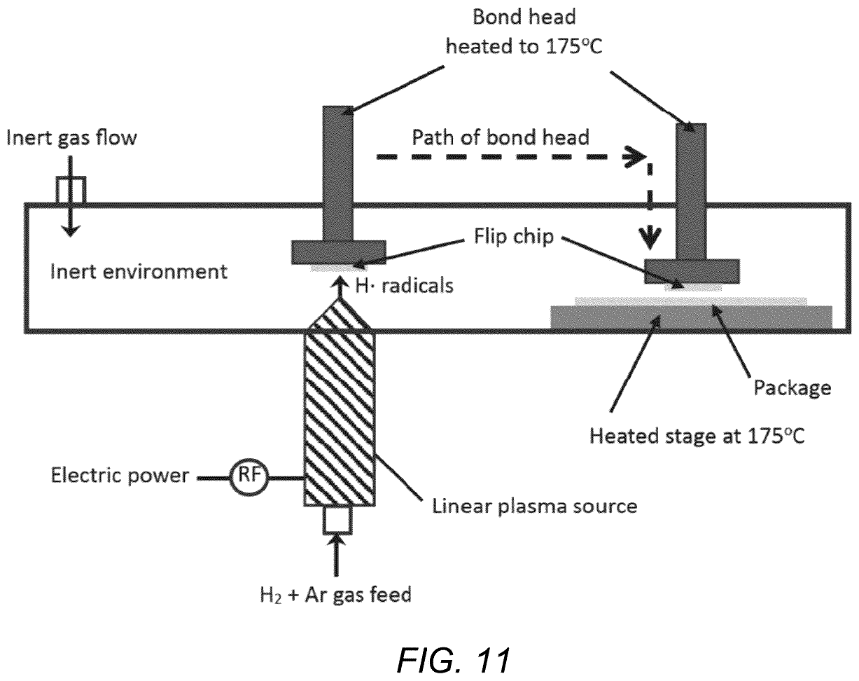

An exemplary apparatus for flux-free flip chip bonding is shown in FIG. 11. The atmospheric pressure plasma, the bond head, and the heated stage are mounted together inside a chamber that is purged with inert gas. The inert gas, argon or nitrogen, flows into the chamber at one end, then past the linear plasma source, the bond head and the heated stage, and exits out the other end. The chamber design and inert gas flow are such that the oxygen concentration is kept below 1,000 ppm, preferably below 100 ppm. A semiconductor package is mounted on the heated stage at an exemplary temperature of 175° C. The semiconductor package may be selected from the group consisting of, but not limited to, an integrated circuit, a die, a wafer, a panel, and a printed circuit board. The bond head has a means of picking up a flip chip such that the army of microbumps on the chip is facing downwards. Then the bond head quickly heats the chip to 175° C., and moves it from left to right, first passing over the linear plasma source, and then over and down onto the semiconductor package. The atmospheric pressure argon and hydrogen plasma exposes the microbumps to a high flux of hydrogen radicals which remove the metal oxide layer from the solder. Next, the bond head moves over the package, aligns with the microbumps or pads on the package surface, and drops down and bonds to the package by application of heat and pressure. Throughout the process of picking up the chip, flipping it, treating it with the plasma and bonding it, the chip is kept in an inert gas environment. This ensures that no metal oxide regrows on the solder surface before bonding is complete. In the process described above, the flip chip and package may be heated to other temperatures in the range of 125 to 250° C., without deviating from the scope of the invention.

The linear plasma source depicted in FIG. 11 is selected so that the width of the plasma beam is equal to or greater than the width of the flip chip. For flip chips that are 2 to 25 mm in width, a 25-mm linear beam plasma may be used. Conversely, for flip chips that are 60 to 100 mm in width, a 100-mm linear beam plasma may be used. Other plasma beam widths may be adopted and not deviate from the scope of this invention. The scan speed necessary to remove the metal oxide from the solder caps on the microbumps depends on the initial thickness of the oxide, the solder composition, and the process temperature. The speeds can vary from 1 to 1,000 mm/s. A preferred speed is one that is just sufficient to remove the metal oxidation from the microbumps, no faster and no slower. Particularly useful scan speeds are those that allow the flip chip to be treated with the argon and hydrogen plasma in 1 to 3 seconds. An exemplary process for a die 25×25 mm² would be to treat it with a 25-mm linear beam plasma at 25 mm/s, yielding an exposure time of 1 second.

In another embodiment of the invention, the apparatus is equipped with two linear beam plasmas mounted onto the inert-gas chamber containing the bond head and the heated stage. One plasma head faces upwards and is used to scan over the flip chip and remove the metal oxidation from the microbumps. The second plasma head faces downwards and is used to scan over the semiconductor package in order to remove metal oxidation from the microbumps or metal pads on its surface. In one embodiment of the invention, the semiconductor package is a 300 mm wafer, and the apparatus is used for flux-free flip chip bonding of chip-on-wafer (CoW).

### Example 5

### Method of Depositing a Thin Film

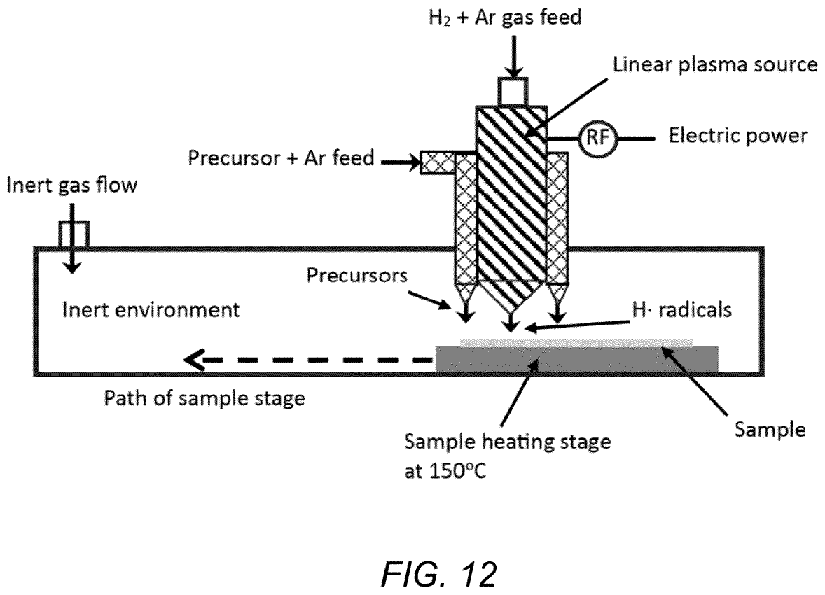

Another embodiment of the invention is a method of depositing thin films with the atmospheric pressure argon and hydrogen plasma. An exemplary apparatus for this embodiment of the invention is presented in FIG. 12. Here, a chamber is supplied with an inert gas flow sufficient to maintain the oxygen concentration below 1,000 ppm, preferably below 100 ppm. A temperature-controlled stage is provided upon which samples are placed and heated to temperatures ranging from 20 to 500° C. Attached to the top of the chamber is an atmospheric pressure plasma source that operates with radio frequency power, for example at 13.56 or 27.12 MHz, and is fed with argon and hydrogen. Mounted on either or both sides of the plasma source are gas injectors for feeding in a volatile precursor that contains the element(s) to be deposited in the thin film. The heated stage is attached to a robot assembly that puts the sample at a fixed z distance from the plasma source and moves the sample at fixed speeds ranging from 2 to 200 mm/s in the x and y directions. This allows the sample to be precisely translated underneath the plasma and precursor gas beams so that a uniform coating is deposited over its entire surface. Suitable z distances are between 1.0 and 10.0 mm.

Materials that may be deposited with the apparatus presented in FIG. 12 include, but are not limited to, organic polymers, metals, and semiconductors. Examples of polymer films that may be deposited by this embodiment of the invention include, but are not limited to, polyethylene, polytetrafluoroethylene, polypropylene, and polyimide. In the case of polyethylene, a dilute concentration of ethylene is fed in an argon flow to the precursor injector and mixed with the hydrogen radicals flowing out of the atmospheric pressure argon and hydrogen plasma. The ethylene and hydrogen radicals react and produce ethylene radicals:

C₂H₆+H·=C₂H₅·+H₂

Then the ethylene radicals collide with the surface, react with one another, and grow a thin film of polyethylene. Example process conditions using a 50-mm-wide plasma beam are 580 W RF power (27.12 MHz), a flow of 55.0 LPM argon with 1.4% hydrogen through the plasma, and a flow of 2.0 LPM argon with 0.2% ethylene through the injector. Suitable sample temperatures range between 20 and 100° C. In this process, the gas injector is design to produce a uniform beam of argon with 0.2% ethylene over a 50 mm width. An example of the robot scan program to use for the polyethylene deposition process is a z distance of 4 mm, and a scan speed in the x direction of 50 mm/s. Multiple scans back and forth are used to build up a polyethylene film between 10 and 1,000 nm thick.

In another embodiment of the invention, thin metal films may be deposited on substrates using the apparatus presented in FIG. 12. Examples of metal films that may be deposited include, but are not limited to, titanium, vanadium, tungsten, nickel, palladium, platinum, copper, silver, gold, and aluminum. A volatile organometallic compound containing the desired metal atom is selected for this process. Suitable vapor pressures for the organometallic compound range from 0.1 to 100.0 Torr at room temperature. These compounds are known to those skilled in the art of thin film deposition. For example, in the case of titanium, a dilute concentration of tetrakis(dimethylamino)titanium (TDMAT) is fed in an argon flow to the precursor injector and mixed with the hydrogen radicals flowing out of the atmospheric pressure argon and hydrogen plasma. The TDMAT and hydrogen radicals react in the gas and on the surface to produce the titanium film:

Ti(NMe₂)₄+4H·=Ti₍ₛ₎+4HNMe₂

Example process conditions using a 50-mm-wide plasma beam are 580 W RF power (27.12 MHz), 55.0 LPM argon with 1.4% hydrogen through the plasma, and 2.0 LPM argon with 0.2% TDMAT through the injector. Suitable sample temperatures range between 10° and 400° C. During deposition the robot scans the substrate underneath the plasma and precursor injectors at a z distance of 4 mm, and a scan speed of 50 mm/s. Multiple scans are used to build up a titanium film between 10 and 1,000 nm thick.

In another embodiment of the invention, the apparatus shown in FIG. 12 is used to deposit semiconductor thin films, including, but not limited to, polycrystalline silicon, amorphous hydrogenated silicon, germanium, gallium arsenide, and gallium nitride. As an example of how to deposit amorphous hydrogenated silicon, the atmospheric pressure argon and hydrogen plasma is operated in conjunction with the injection of a dilute stream of disilane in argon. The hydrogen radicals generated by the plasma combine with the disilane in the gas and on the substrate surface to produce the amorphous hydrogenated silicon film:

1.2Si₂H₆+H·=SiHₓ₍ₛ₎+½(4−x)H₂

Example process conditions using a 50-mm-wide plasma beam are 580 W RF power (27.12 MHz), a gas flow of 55.0 LPM argon with 1.4% hydrogen through the plasma, and a gas flow of 2.0 LPM argon with 0.2% disilane through the injector. Suitable sample temperatures range between 150 and 500° C. A robot scan program similar to that describe above would be used in this case as well. Many other semiconductor films may be deposited using the principles herein, and would be understood to those skilled in the art.

This concludes the description, including the preferred embodiments of the invention. The foregoing description including the preferred embodiment of the invention has been presented for the purposes of illustration. It is not intended to be exhaustive or to limit the invention to the precise forms disclosed. Many modifications and variations are possible within the scope of the foregoing teachings. Additional variations of the invention may be devised without departing from the inventive concept as set forth in the following claims.

What is claimed is:

1. An apparatus for removing metal oxide layers from metals comprising:
a chamber filled with inert gas such that an oxygen concentration in the chamber is kept below 1,000 parts per million;
an atmospheric pressure plasma source disposed in the chamber that is fed with argon and hydrogen, generates hydrogen radicals, and operates at a linear power density greater than 10.0 W/mm;
a temperature-controlled plate disposed within the chamber, wherein said temperature-controlled plate supports a substrate including metal features with a metal oxide layer upon the surface of the metal features; and
a means for moving the substrate and the atmospheric pressure plasma source relative to each other, such that the hydrogen radicals flowing out of the plasma source contact and convert the metal oxide layer to metal and water vapor.

2. The apparatus of claim 1, wherein the plasma source comprises a linear opening that produces a beam of reactive gas between 1 and 300 mm wide.

3. The apparatus of claim 2, wherein the linear opening is at least as wide as the substrate containing the metal features with the metal oxide layer to be removed.

4. The apparatus of claim 1, wherein the power supply operates at a radio frequency of 13.56 or 27.12 MHz.

5. The apparatus of claim 1, wherein the inert gas is selected from the group argon and nitrogen.

6. The apparatus of claim 1, wherein the hydrogen added to the argon gas flow through the plasma is at a concentration between 0.1 to 5.0 volume %.

7. The apparatus of claim 1, wherein the substrate is heated to a temperature between 20 and 250° C.

8. The apparatus of claim 1, wherein the substrate is selected from the group of semiconductor materials comprising, integrated circuits, chips, dies, wafers, panels, chip packages, and printed circuit boards.

9. The apparatus of claim 1, wherein the metal is selected from the group comprising, nickel, palladium, platinum, copper, silver, gold, gallium, indium, tin, lead, bismuth and alloys thereof.

10. The apparatus of claim 1, wherein the metal features are a two-dimensional array of microbumps with copper pillars and tin alloy solder caps having a diameter less than 100 microns, and the metal oxide layer on the tin alloy solder caps is removed.

11. A method of removing metal oxide layers from metals comprising:
filling a chamber with inert gas such that an oxygen concentration in the chamber is kept below 1,000 parts per million;
disposing an atmospheric pressure plasma source within the chamber and operating it with argon and hydrogen gas flows and a radio frequency power source with a power density greater than 10.0 W/mm to generate hydrogen radicals;
disposing a temperature-controlled plate within the chamber, wherein said temperature-controlled plate supports a substrate including metal features with a metal oxide layer upon the surface of the metal features; and
moving the substrate and the plasma source relative to each other, such that the hydrogen radicals flowing out of the plasma source contact and convert the metal oxide layer to metal and water vapor.

12. The method of claim 11, wherein the plasma source comprises a linear opening that produces a beam of reactive gas between 1 and 300 mm wide.

13. The method of claim 12, wherein the linear opening is at least as wide as the substrate containing the metal features with the metal oxide layer to be removed.

14. The method of claim 11, wherein the radio frequency power supply operates at 13.56 or 27.12 MHz.

15. The method of claim 11, wherein the inert gas is selected from the group argon and nitrogen.

16. The method of claim 11, wherein the hydrogen in the gas flow through the plasma source is at a concentration between 0.1 to 5.0 volume %.

17. The method of claim 11, wherein the substrate is heated to a temperature between 2° and 250° C.

18. The method of claim 11, wherein the substrate is selected from the group of semiconductor materials comprising, integrated circuits, chips, dies, wafers, panels, chip packages, and printed circuit boards.

19. The method of claim 11, wherein the metal is selected from the group comprising, nickel, palladium, platinum, copper, silver, gold, gallium, indium, tin, lead, bismuth and alloys thereof.

20. The method of claim 11, wherein the metal features are a two-dimensional array of microbumps with copper pillars and tin alloy solder caps having a diameter less than 100 microns, and the oxidation on the tin alloy solder caps is removed.

21. An apparatus for forming metal interconnects comprising:
a chamber filled with inert gas such that an oxygen concentration in the chamber is kept below 1,000 parts per million;
an atmospheric pressure plasma source disposed within the chamber, wherein said atmospheric pressure plasma source is fed with argon and hydrogen and operates at a linear power density greater than 10.0 W/mm;
a bond head disposed in the chamber, wherein said bond head holds a flip chip with microbumps on it at a temperature between 20 and 250° C.;
a temperature-controlled plate disposed inside the chamber and heated to between 20 and 250° C., wherein said temperature-controlled plate supports a substrate including microbumps or metal pads that are of substantially similar dimensions of the microbumps on the flip chip; and
a means for scanning the bond head with the flip chip over the plasma source and down onto the substrate, such that the metal oxidation on the microbumps is removed by the plasma and the flip chip is bonded to the substrate forming said metal interconnects.

22. A method of forming metal interconnects comprising:
filling a chamber with inert gas such that an oxygen concentration in the chamber is kept below 1,000 parts per million;
disposing an atmospheric pressure plasma source within the chamber, wherein said source is fed with argon and hydrogen and operates at a linear power density greater than 10.0 W/mm;
mounting a bond head in the chamber, wherein said bond head holds a flip chip with microbumps on it at a temperature between 20 and 250° C.;
disposing a temperature-controlled plate inside the chamber and heating it to between 20 and 250° C., wherein said temperature-controlled plate supports a substrate including microbumps or metal pads that are of substantially similar dimensions of the microbumps on the flip chip; and
scanning the bond head with the flip chip over the plasma source and down onto the substrate, such that the metal oxidation on the microbumps is removed by the plasma and the flip chip is bonded to the substrate forming said metal interconnects.

23. An apparatus for plasma-enhanced chemical vapor deposition of thin films comprising:
a chamber filled with inert gas such that an oxygen concentration in the chamber is kept below 1,000 parts per million;
an atmospheric pressure plasma source disposed within the chamber, wherein said atmospheric pressure plasma source is fed with argon and hydrogen and operates at a linear power density greater than 10.0 W/mm to generate hydrogen radicals;
a gas injector disposed in the chamber, wherein said gas injector is fed with volatile precursor molecules that include one or more elements to be deposited in a thin film;
a temperature-controlled plate placed in the chamber and heated to between 20 and 500° C., wherein said plate holds a substrate; and
a means for moving the substrate and the plasma source and gas injector relative to each other, such that the hydrogen radicals flowing out of the plasma source combine with the precursor molecules flowing out of the injector and react together and deposit the thin film on the substrate.

24. A method of depositing a thin film on a substrate comprising:
filling a chamber with inert gas such that an oxygen concentration in the chamber is kept below 1,000 parts per million;
disposing an atmospheric pressure plasma source within the chamber, wherein said atmospheric pressure plasma source is fed with argon and hydrogen and operates at a linear power density greater than 10.0 W/mm to generate hydrogen radicals;
disposing a gas injector in the chamber, wherein said gas injector is fed with volatile precursor molecules that include one or more elements to be deposited in a thin film;
disposing a temperature-controlled plate in the chamber and heating the temperature-controlled plate to between 20 and 500° C., wherein said temperature-controlled plate supports a substrate; and
moving the substrate and plasma source and gas injector relative to each other, such that the hydrogen radicals flowing out of the plasma source combine with the precursor molecules flowing out of the injector and react together and deposit the thin film on the substrate.
